(19) United States
(12) Patent Application Publication
(10) Pub. No.: US 2012/0160309 A1
(43) Pub. Date: Jun. 28, 2012

(54) SOLAR CELL

(75) Inventors: Sung-Su KIM, Yongin-si (KR); Hyun-Chul KIM, Yongin-si (KR); Joo-Sik JUNG, Yongin-si (KR); Suk-Beom YOU, Yongin-si (KR)

(73) Assignee: SAMSUNG SDI CO., LTD., Yongin-si (KR)

(21) Appl. No.: 13/109,724

(22) Filed: May 17, 2011

Related U.S. Application Data
(60) Provisional application No. 61/426,796, filed on Dec. 23, 2010.

(51) Int. Cl. H01L 31/0224; H01L 51/44

(52) U.S. Cl. 136/255

(57) ABSTRACT

Disclosed herein is a dye-sensitized solar cell including a first substrate having a first side and a second side opposite the first side, a second substrate positioned on the second side of the first substrate, a first electrode unit positioned between the first substrate and the second substrate and disposed on the first substrate and a second electrode unit positioned between the first electrode unit and the second substrate and disposed on the second substrate. At least one of the first electrode unit and the second electrode unit may include a current collector electrode and a plurality of electrodes electrically connected to the current collector electrode. The plurality of electrodes may be positioned within an effective area and the current collector electrode may be positioned outside the effective area. A first resistance of the current collector electrode may be less than a second resistance of the plurality of electrodes.

### CROSS-REFERENCE TO RELATED APPLICATIONS

The present application is a non-provisional application claiming priority to and the benefit of U.S. Provisional Application No. 61/426,796, filed on Dec. 23, 2010, the content of which is hereby incorporated by reference in its entirety.

### BACKGROUND

1. Field of the Disclosure

The present disclosure relates to a solar cell.

2. Description of the Related Technology

Recently, in order to solve energy-related problems, various studies have been conducted regarding the substitution of existing fossil fuels. A wide range of studies have been conducted on how to use natural energy sources such as wind power, atomic power, and solar power. Unlike other energy sources, solar cells use solar energy that is both unlimited and environmentally friendly. Since selenium (Se) solar cells were developed in 1983 additional research has been performed on silicon solar cells. It is costly to manufacture it takes time to commercialize silicon solar cells, and it is difficult to improve the efficiency of silicon solar cells. To overcome the aforementioned problems, attempts have been made to develop dye-sensitized solar cells that may be manufactured at relatively low cost. Dye-sensitized solar cells include photosensitive dyes capable of absorbing visible light and generating excitons which are bound electron-hole pairs, and transition metal oxides for transferring generated electrons.

### SUMMARY OF CERTAIN INVENTIVE ASPECTS

According to one or more embodiments of the present disclosure, solar cell energy efficiency is improved.

In one aspect, a dye-sensitized solar cell includes, for example, a first substrate having a first side and a second side opposite the first side, a second substrate positioned on the second side of the first substrate, a first electrode unit positioned between the first substrate and the second substrate and disposed on the first substrate, and a second electrode unit positioned between the first electrode unit and the second substrate and disposed on the second substrate. In some embodiments, at least one of the first electrode unit and the second electrode unit includes, for example, a current collector electrode and a plurality of electrodes electrically connected to the current collector electrode. In some embodiments, the plurality of electrodes is positioned within an effective area. In some embodiments, the current collector electrode is positioned outside the effective area. In some embodiments, a first resistance of the current collector electrode is less than a second resistance of the plurality of electrodes.

In some embodiments, a current collector electrode cross-section area is greater than a cross-section area of each of the plurality of electrodes. In some embodiments, a current collector electrode width is greater than a width of each of the plurality of electrodes. In some embodiments, a current collector electrode thickness is greater than a thickness of each of the plurality of electrodes. In some embodiments, the current collector electrode includes, for example, a first current collector electrode and a second current collector electrode. In some embodiments, the first current collector electrode includes, for example, a first grid electrode and a semiconductor electrode. In some embodiments, the second current collector electrode includes, for example, a second grid electrode and a counter electrode. In some embodiments, the effective area includes, for example, an electrolyte disposed between the first substrate and the second substrate. In some embodiments, a sealing member is disposed around a perimeter of the effective area and is configured to seal the electrolyte between the first substrate and the second substrate. In some embodiments, the current collector includes, for example, a material with less resistance than the plurality of electrodes. In some embodiments, the current collector electrode is formed of silver (Ag), aluminum (Al) or copper (Cu). In some embodiments, the width of the current collector is more than about 2 times greater than the width of each of the plurality of electrodes. In some embodiments, a ratio of the current collector electrode width to a width of each of the plurality of electrode is between about 2 and about 4.

In another aspect, a building integrated photovoltaic (BIPV) device is provided that includes a dye-sensitized solar cell. In some embodiments, at least part of the effective area is positioned in a window. In some embodiments, at least part of the current collector electrode is positioned in a window frame.

In another aspect, a dye-sensitized solar cell includes a first substrate having a first side and a second side opposite the first side, a second substrate positioned on the second side of the first substrate, a first electrode unit positioned between the first substrate and the second substrate and disposed on the first substrate, and a second electrode unit positioned between the first electrode unit and the second substrate and disposed on the second substrate. In some embodiments, at least one of the first electrode unit and the second electrode unit includes, for example, a current collector electrode and a plurality of electrodes electrically connected to the current collector electrode. In some embodiments, the plurality of electrodes is positioned within an effective area. In some embodiments, the current collector electrode is positioned outside the effective area. In some embodiments, a current collector electrode width is greater than a width of each of the plurality of electrodes.

In some embodiments, a ratio of the current collector electrode width to a width of each of the plurality of electrode is between about 2 and about 4. In some embodiments, a current collector electrode thickness is greater than a thickness of each of the plurality of electrodes. In some embodiments, the effective area includes, for example, an electrolyte disposed between the first substrate and the second substrate. In some embodiments, a sealing member is disposed around a perimeter of the effective area and is configured to seal the electrolyte between the first substrate and the second substrate. In some embodiments, a current collector electrode cross-section area is greater than a cross-section area of each of the plurality of electrodes. In some embodiments, the width of the current collector is more than about 2 times greater than the width of each of the plurality of electrodes. In some embodiments, the current collector electrode includes, for example, a first current collector electrode and a second current collector electrode. In some embodiments, the first current collector electrode includes, for example, a first grid electrode and a semiconductor electrode. In some embodiments, the second current collector electrode includes, for example, a second grid electrode and a counter electrode. In some embodiments, the current collector includes, for example, a material with less resistance than the plurality of electrodes. In some embodiments, the current collector electrode is formed of silver (Ag), aluminum (Al) or copper (Cu).

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus, system or method according to some of the described embodiments can have several aspects, no single one of which necessarily is solely responsible for the desirable attributes of the apparatus, system or method. After considering this discussion, and particularly after reading the section entitled “Detailed Description of Certain Inventive Embodiments” one will understand how illustrated features serve to explain certain principles of the present disclosure.

FIG. 1 is a conceptual view for explaining a principle of driving a dye-sensitized solar cell.

FIG. 2 is an exploded perspective view illustrating a structure of an instant dye-sensitized solar cell including current collector electrodes.

FIG. 3 is a plan view illustrating a first electrode unit of the dye-sensitized solar cell of FIG. 2.

FIG. 4 is a cross-sectional view taken along line IV-IV of FIG. 2.

FIG. 5 is a graph illustrating a relationship between a power and the width of a current collector electrode.

FIG. 6 is a graph illustrating a relationship between a fill factor and the width of a current collector electrode.

FIGS. 7 and 8 are graphs illustrating potential voltages of a first electrode and a first current collector electrode in an area B of FIG. 3.

FIG. 9 is a graph illustrating a relationship between a voltage and a current density.

FIG. 10 is a graph illustrating a relationship between a voltage and a power.

FIG. 11 is a plan view illustrating a modification of the first electrode unit of FIG. 3.

### DETAILED DESCRIPTION OF CERTAIN INVENTIVE EMBODIMENTS

In the following detailed description, only certain exemplary embodiments have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements. Since the disclosure may be modified in various ways and have various embodiments, the disclosure will be described in detail with reference to the drawings. However, it should be understood that the disclosure is not limited to a specific embodiment but includes all changes and equivalent arrangements and substitutions included in the spirit and scope of the disclosure. In the following description, if the detailed description of the already known structure and operation may confuse the subject matter of the present disclosure, the detailed description thereof will be omitted.

While such terms as “first,” “second,” etc., may be used to describe various components, such components must not be limited to the above terms. The above terms are used only to distinguish one component from another. Terms used in the following description are to describe specific embodiments and is not intended to limit the disclosure. The expression of singularity includes plurality meaning unless the singularity expression is explicitly different in context. It should be understood that the terms “comprising,” “having,” “including,” and “containing” are to indicate features, numbers, steps, operations, elements, parts, and/or combinations but not to exclude one or more features, numbers, steps, operations, elements, parts, and/or combinations or additional possibilities.

Embodiments of the present disclosure will now be described more fully with reference to the accompanying drawings.

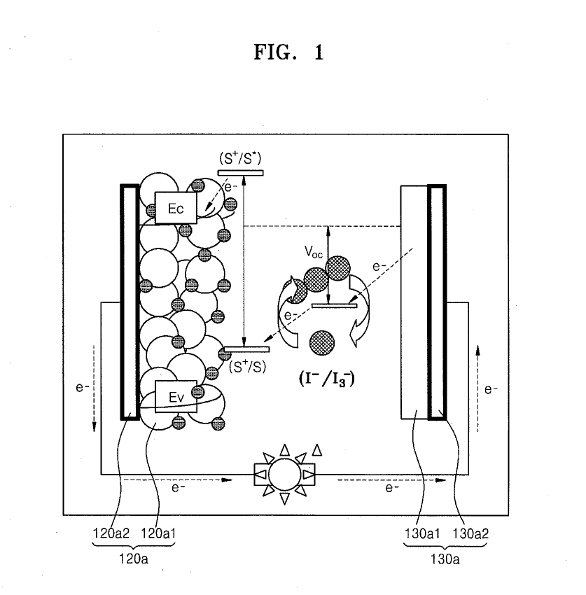

A principle of driving a dye-sensitized solar cell will now be explained with reference to FIG. 1. When sunlight is incident on a dye-sensitized solar cell, photons with sufficient energy transfer energy to dye molecules (not shown) on a surface of a first grid electrode 120a1, the dye molecules change from a ground state to an exited state to generate electron-hole pairs, and excited electrons e⁻ are injected into a conduction band of the first grid electrode 120a1. The electrons e⁻ emitted from the dye molecules generate electricity while moving according to a chemical diffusion gradient. Here, the dye molecules are photosensitive dye molecules capable of absorbing visible light and generating electron-hole pairs. In addition, each of the dye molecules is comparably small, and thus, to contain a large number of dye molecules, the first grid electrode 120a1 is used as a scaffold for the dye molecules.

Referring to FIG. 1, the dye molecules change to an excited state (S⁺/S*) from a ground state (S⁺/S), and the excited dye molecules are oxidized by emitting the electrons e⁻. Here, the oxidized dye molecules are reduced at the same time the iodine ions are oxidized in a redox reaction. More specifically, the oxidized dye molecules are reduced by receiving electrons e⁻ from iodine ions in a redox electrolyte (I⁻/I³⁻) disposed between a semiconductor electrode 120a2 and a second grid electrode 130a1. Meanwhile, the excited electrons e⁻ are injected into a conduction band of the first grid electrode 120a1, and transferred to the second grid electrode 130a1 via the semiconductor electrode 120a2, an external circuit, and the counter electrode 130a2. The second grid electrode 130a1 may be formed of platinum. The electrons e⁻ reaching the second grid electrode 130a1 reduce the oxidized iodine ions. As such, by absorbing the sunlight, the dye-sensitized solar cell induces a transfer of the electrons e⁻. This transfer of electrons e⁻ causes current to flow and the apparatus to function as a solar cell.

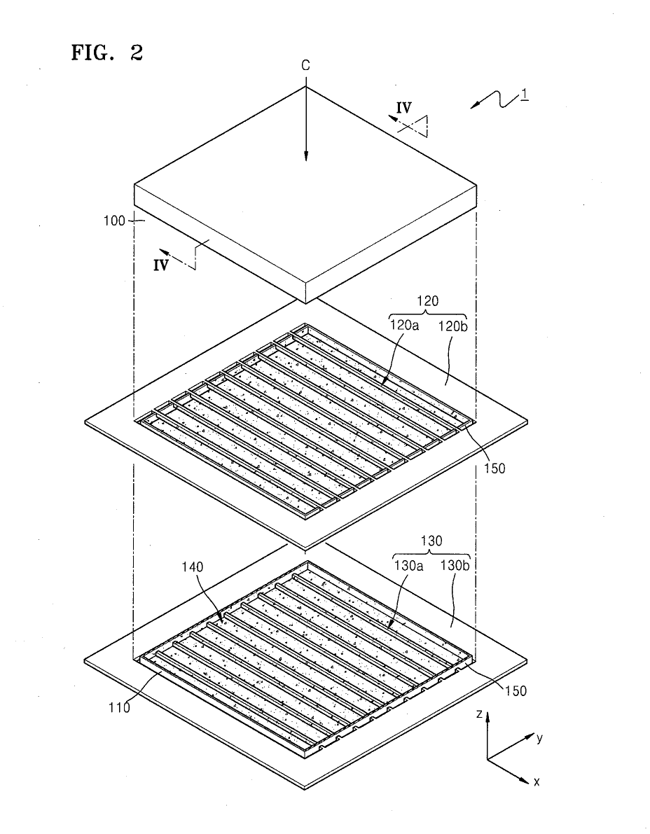

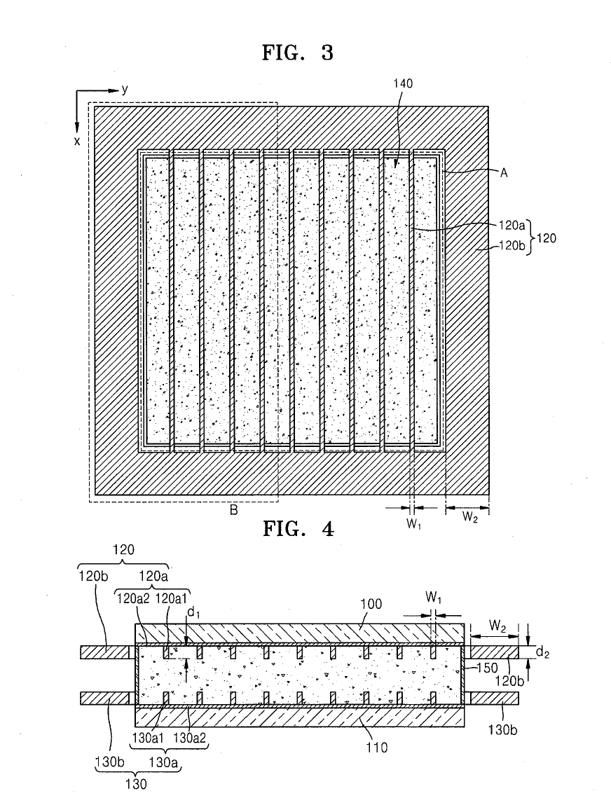

A structure of a dye-sensitized solar cell 1 will now be described with reference to FIGS. 2 through 4. FIG. 2 is an exploded perspective view illustrating a structure of the dye-sensitized solar cell 1 including first and second current collector electrodes 120b and 130b, according to an embodiment of the present disclosure. FIG. 3 is a plan view illustrating first electrode unit 120 of the dye-sensitized solar cell 1 of FIG. 2. FIG. 4 is a cross-sectional view taken along line IV-IV of FIG. 2.

Referring to FIGS. 2 through 4, the dye-sensitized solar cell 1 includes a first substrate 100, a second substrate 110, the first electrode unit 120, a second electrode unit 130, an electrolyte 140, and a sealing member 150. Each of the first substrate 100 and the second substrate 110 may be formed of transparent glass or polymer. The polymer may include, for example, polyacrylate, polyethylene terephthalate, polyethylene naphthalate, polycarbonate, polyarylate, polyetherimide, polyethersulfone, or polyimide.

The first electrode unit 120 may include the first electrode 120a and the first current collector electrode 120b. Here, the first electrode 120a may include the first grid 130a1 and the semiconductor electrode 120a2. The second electrode unit 130 may include the second electrode 130a and the second current collector electrode 130b. The second electrode 130a may include the second grid electrode 130a1 and the counter electrode 130a2.

Each of the semiconductor electrode 120a2 and the counter electrode 130a2 may be formed of a transparent conductor. For example, each of the semiconductor electrode 120a2 and the counter electrode 130a2 may include an inorganic conductive material, such as indium tin oxide (ITO), fluorine-doped tin oxide (FTO) or antimony doped tin oxide (ATO), or an organic conductive material, such as polyacetylene or polythiophene.

For activating redox couples, the second grid electrode 130a1 may include, for example, platinum (Pt), gold (Au), nickel (Ni), copper (Cu), silver (Ag), indium (In), ruthenium (Ru), palladium (Pd), rhodium (Rh), iridium (Ir), osmium (Os), carbon (C), a conductive polymer, or a combination thereof. To improve an oxidation-reduction catalytic reaction, a surface of the second grid electrode 130a1 facing the semiconductor electrode 120a2 may include a micro structure to increase a surface area. For example, if the second grid electrode 130a1 is formed of, for example, platinum, the second grid electrode 130a1 may be in a platinum black state, and if the second grid electrode 130a1 is formed of, for example, carbon, the second grid electrode 130a1 may be in a porous state. The platinum black state may be achieved by anodizing platinum or treating platinum using a chloroplatinic acid, and the porous state may be achieved by sintering carbon particles or burning an organic polymer.

The first grid electrode 120a1 may be configured to adsorb photosensitive dyes. Nano particles having uniform average diameters are uniformly distributed in the first grid electrode 120a1, and the first grid electrode 120a1 may have a porous surface with an appropriate roughness. The first grid electrode 120a1 may be formed of, for example, TiO₂, SnO₂, ZnO, WO₃, Nb₂O₅, TiSrO₃, or a mixture thereof.

The semiconductor electrode 120a2 may be capable of absorbing solar energy and transferring electrons to an external circuit. Dye molecules absorb visible light to generate electron-hole pairs, and the first grid electrode 120a1 adsorbs the dye molecules and transfers electrons generated in the dye molecules. The electrolyte 140 is configured to reduce oxidized dye molecules. The sealing member 150 may be configured to seal the electrolyte 140 from leaking between the first substrate 100 and the second substrate 110. Here, the counter electrode 130a2 and/or the semiconductor electrode 120a2 may pass through the sealing member 150 to be electrically connected outside the solar cell.

A larger dye-sensitized solar cell 1 increases resistance of the semiconductor electrode 120a2 and/or the counter electrode 130a2. Accordingly, the dye-sensitized solar cell 1 may electrically connect the semiconductor electrode 120a2 to the first current collector electrode 120b. Also, the dye-sensitized solar cell 1 may electrically connect the counter electrode 130a2 to the second current collector electrode 130b to improve current flow.

The first current collector electrode 120b may be electrically connected to the first electrode 120a. The second current collector electrode 130b may be electrically connected to the second electrode 130a. The first current collector electrode 120b and the second current collector electrode 130b may have similar structures. Although the following explanation will be focused on the first current collector electrode 120b, the scope of the present embodiment is not limited thereto. Further, the second current collector electrode 130b may have an identical or similar structure to that of the first current collector electrode 130a.

Referring to FIGS. 2 through 4, the first current collector electrode 120b may be electrically connected to the first electrode 120a such that current may flow to the second grid electrode 130a1 and the counter electrode 130a2. Here, the first current collector electrode 120b may be disposed outside the sealing member 150 and positioned to surround the dye-sensitized solar cell 1. That is, the larger the dye-sensitized solar cell 1, the longer the first electrode 120a. A longer first electrode 120a may increase error in electron movement. However, since the first current collector electrode 120b is electrically connected to the first electrode 120a and has a greater width W₂ maximizing current flow, a total resistance of the first electrode unit 120 is reduced, thereby minimizing loss of electrons. Also, the first current collector electrode 120b may be electrically connected to both sides of the first electrode 120a, thereby shortening an electron transport distance. Here, the first current collector electrode 120b may include a conductive material having a sufficient width W₂ and a low resistance. That is, the width W₂ of the first electrode 120a may be larger than a width W₁ of the first grid electrode 120a1, thereby making electrons move more smoothly. Also, the first current collector electrode 120b may include a material with a resistance that is equal to or less than that of the semiconductor electrode 120a2. For example, the first current collector electrode 120b may include any one of silver (Ag), aluminum (Al), and copper (Cu). The first current collector electrode 120b is not limited thereto, and may include any suitable metal or conductive material. Also, the second current collector electrode 130b may include a conductive material having a sufficient width W₂ and a low resistance like the first current collector electrode 120b.

The dye-sensitized solar cell 1 may include an effective area A, which may be configured to receive light, and a dead area, which may be configured to block light or simply configured to not receive light. The effective area A illustrated within a dotted line in FIG. 3 may be an area capable of receiving light. If the dye-sensitized solar cell 1 is used as, for example, a building integrated photovoltaic (BIPV) material in a window, an area within a window frame becomes a dead area that may not receive sunlight. That is, such a dead area may be an area outside the effective area A in FIG. 3. The first current collector electrode 120b may be located in the dead area. If the first current collector electrode 120b is located in the effective area A, the first current collector electrode 120b may block or scatter light, thereby increasing the risk that the amount of light is reduced. However, since the first current collector electrode 120b is located outside the effective area A as shown in FIGS. 2 through 4, the first current collector electrode 120b may not affect the efficiency or the like of the dye-sensitized solar cell 1. Also, a resistance of the first electrode unit 120 may be reduced due to the dead area corresponding to a window frame or the like.

Referring to FIGS. 2 through 4, although the first electrode unit 120 is located closer to a side on which light C is incident than the second electrode unit 130, the structure of the dye-sensitized solar cell 1 is not limited thereto. That is, the second electrode unit 130 may be located closer to the side on which the light C is incident.

In FIGS. 2 through 4, if the dye-sensitized solar cell 1 is used as a power generator, instead of as a BIPV, since the second substrate 110 does not need to transmit light, the second substrate 110 may be a metal member. If the second substrate 110 is a metal member, the semiconductor electrode 120a2 may be unnecessary and the first grid electrode 120a1 may be formed on the second substrate 110. If the second substrate 110 is a metal member, which easily conducts electrons, the second current collector electrode 130b may be omitted from the second electrode unit 130. In this case, since the first substrate 100 on which light is incident is a transparent substrate, the first current collector electrode 120b electrically connected to the first electrode 120a may be necessary.

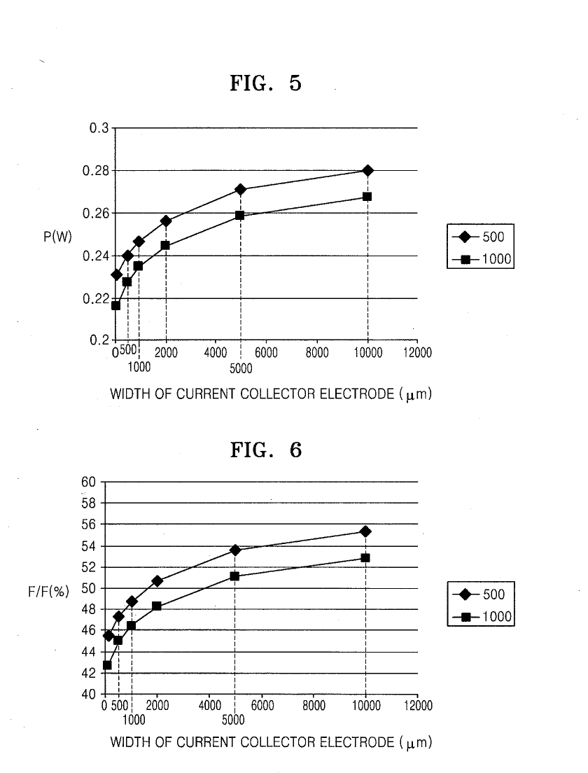

Effects of examples using the first current collector electrode 120b will now be described with reference to Table 1 and FIGS. 5 through 10.

Referring to Table 1 and FIGS. 5 and 6, in a First Embodiment, a width W₁ of the first electrode 120a is 1000 μm, and a thickness d₁ of the first electrode 120a is 10 μm. In a Second Embodiment, a width W₁ of the first electrode 120a is 500 μm and a thickness d₁ of the first electrode 120a is 10 μm. In FIG. 4, a width W₁ and a thickness d₁ of the first electrode 120a are exaggerated for convenience, and the scope of the present disclosure is not limited thereto. An experiment was performed in such a manner that an aperture ratio in the First Embodiment and the Second Embodiment is 90%. Here, a power P and a fill factor (F/F) were obtained by increasing a width W₂ of the first current collector electrode 120b from 0 to 10000 μm. Here, a thickness d₂ of the first current collector electrode 120b is 10 μm.

TABLE 1

| | First Embodiment | | Second Embodiment | |
|---|---|---|---|---|
| Width W₂ of current | (1000 μm) | | (500 μm) | |
| collector (μm) | P (W) | F/F (%) | P (W) | F/F (%) |
| 0 | 0.215858 | 42.70065 | 0.230402 | 45.55974 |
| 500 | 0.22766 | 45.0221 | 0.23945 | 47.35173 |
| 1000 | 0.234947 | 46.46137 | 0.246455 | 48.73271 |
| 2000 | 0.244328 | 48.31101 | 0.256029 | 50.61583 |
| 5000 | 0.258387 | 51.08401 | 0.270695 | 53.52075 |
| 10000 | 0.267531 | 52.88612 | 0.28019 | 55.38258 |

Referring to Table 1 and FIGS. 5 and 6, it is found that when the width W₂ of the first current collector electrode 120b ranges from about 0 to about 2000 μm, the power P and the fill factor F/F is sharply increased. That is, when the width W₂ of the first current collector electrode 120b is more than about 2 times greater than the width W₁ of the first electrode 120a, an increase in the power P and the fill factor F/F is stabilized. In detail, the width W₂ of the first current collector electrode 120b may be about 2 to about 4 times greater than the width W₁ of the first electrode 120a.

Accordingly, when the width W₁ of the first electrode 120a is about 500 μm, the width W₂ of the first current collector electrode 120b may be about 1000 μm or more. Also, when the width W₁ of the first electrode 120a is about 1000 μm, the width W₂ of the first current collector electrode 120b may be about 2000 μm or more.

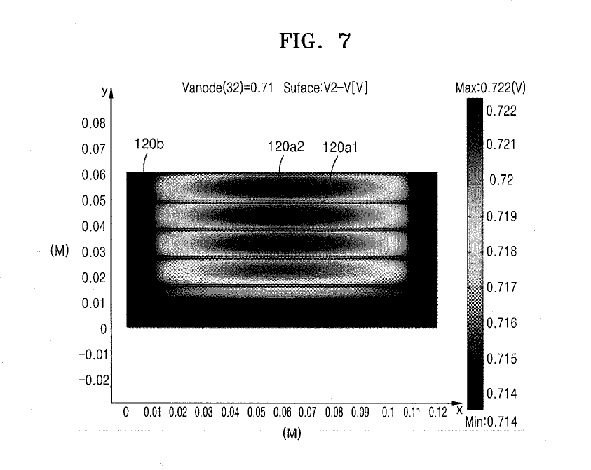

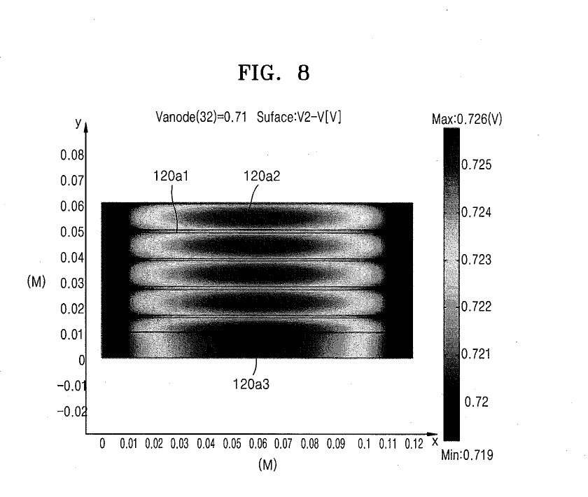

FIGS. 7 and 8 are graphs illustrating potential voltages v of the first current collector electrode 120b and the first electrode 120a in an area B of FIG. 3. A large voltage drop may occur in a region where a potential voltage v is high. Such a voltage drop may increase power loss. Accordingly, a region where a potential voltage v is high may be a place where a resistance is relatively high. FIG. 7 is a graph illustrating a potential voltage when a width W₁ of the first electrode 120a is 1000 μm, a thickness d₁ of the first electrode 120a is 10 μm, and a width W₂ of the first current collector electrode 120b is 2000 μm, as in the First Embodiment. FIG. 8 is a graph illustrating a Comparative Example in which the dye-sensitized solar cell 1 includes a second semiconductor electrode 120a3 extending from the semiconductor electrode 120a2, instead of the first current collector electrode 120b. That is, the Comparative Example of FIG. 8 is an example where the existing semiconductor electrode 120a2 is located without the first current collector electrode 120b, which connects both ends of the first grid electrode 120a1.

In FIG. 7, a dark blue color portion of the first current collector electrode 120b indicates a portion with a low potential voltage. In FIGS. 7 and 8, a dark red portion at the center of the semiconductor electrode 120a2 indicates a portion with a high potential voltage. When FIGS. 7 and 8 are compared, it is found that a potential voltage of the first current collector electrode 120b is low. That is, resistance is low in an embodiment using the first current collector electrode 120b.

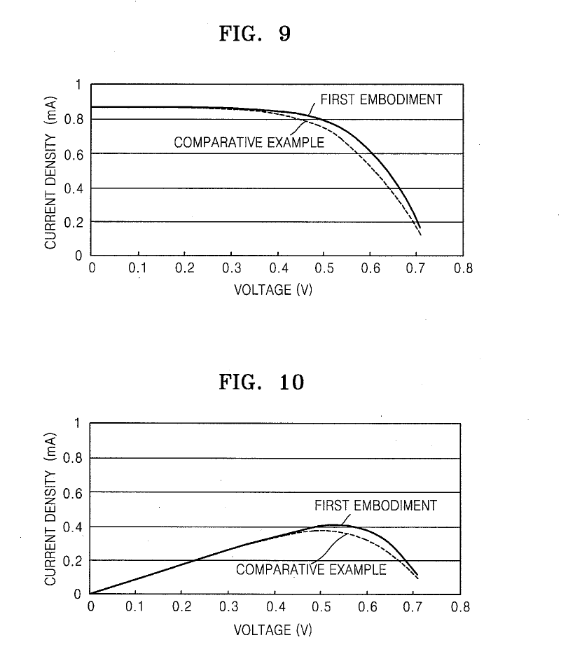

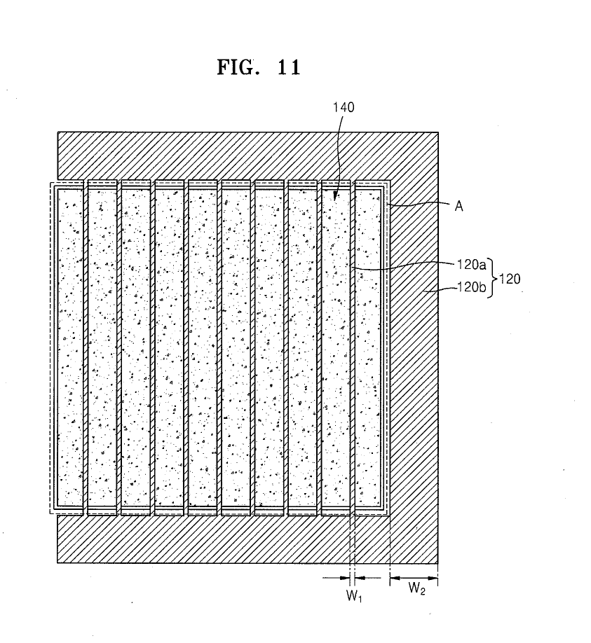

FIG. 9 is a graph illustrating a relationship between a voltage V and a current density mA. FIG. 10 is a graph illustrating a relationship between a voltage V and a power mW. Referring to FIG. 9, a current density at the same voltage is higher in the First Embodiment than in the Comparative Example. Also, referring to FIG. 10, a power at the same voltage is higher in the First Embodiment than in the Comparative Example. Accordingly, when the first current collector electrode 120b is used, a current density and a power of the dye-sensitized solar cell 1 at the same voltage are improved.

FIG. 11 is a plan view illustrating a modification of the first electrode unit 120 of FIG. 3. Structures of the current collector electrodes 120b and 130b are not limited to those shown in FIGS. 2 through 4. Referring to FIG. 11, the first current collector electrode 120b may be formed to surround at least a part of the dye-sensitized solar cell 1. In FIG. 11, the first current collector electrode 120b may be formed in a [symbol] -shape. That is, the first current collector electrode 120b may be formed in such a manner that the first current collector electrode 120b is electrically connected to both ends of the first electrode 120a extending in one direction, and surrounds at least a part of the dye-sensitized solar cell 1. Accordingly, resistances of electrons moving through the first electrode 120a are reduced, thereby improving the efficiency of the dye-sensitized solar cell 1.

According to the dye-sensitized solar cell 1 of the one or more embodiments of present disclosure, the current collector electrodes 120b and 130b may be located outside the sealing member 150 so as not to cover the effective area A. Also, a width of each of the current collector electrodes 120b and 130b may be more than about two times greater than a width of the first electrode 120a or the second electrode 130a. Alternatively, a width of each of the current collector electrodes 120b and 130b may be at least about two to about four times greater than a width of the first electrode 120a or the second electrode 130a.

While the dye-sensitized solar cell 1 has been exemplarily described in the embodiments, the present disclosure is not limited thereto, and the current collector electrodes 120b and 130b may be used in order to reduce a resistance of an electrode and to use a dead area in a solar cell.

While the present invention has been described in connection with certain exemplary embodiments, it will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Thus, while the present disclosure has described certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A dye-sensitized solar cell, comprising:
a first substrate having a first side and a second side opposite the first side;
a second substrate positioned on the second side of the first substrate;
a first electrode unit positioned between the first substrate and the second substrate and disposed on the first substrate; and
a second electrode unit positioned between the first electrode unit and the second substrate and disposed on the second substrate,
wherein at least one of the first electrode unit and the second electrode unit comprises a current collector electrode and a plurality of electrodes electrically connected to the current collector electrode,
wherein the plurality of electrodes are positioned within an effective area,
wherein the current collector electrode is positioned outside the effective area, and
wherein a first resistance of the current collector electrode is less than a second resistance of the plurality of electrodes.

2. The dye-sensitized solar cell of claim 1, wherein a current collector electrode cross-section area is greater than a cross-section area of each of the plurality of electrodes.

3. The dye-sensitized solar cell of claim 1, wherein a current collector electrode width is greater than a width of each of the plurality of electrodes.

4. The dye-sensitized solar cell of claim 1, wherein a current collector electrode thickness is greater than a thickness of each of the plurality of electrodes.

5. The dye-sensitized solar cell of claim 1, wherein the current collector electrode comprises a first current collector electrode and a second current collector electrode, wherein the first current collector electrode comprises a first grid electrode and a semiconductor electrode, and wherein the second current collector electrode comprises a second grid electrode and a counter electrode.

6. The dye-sensitized solar cell of claim 1, wherein the effective area comprises an electrolyte disposed between the first substrate and the second substrate.

7. The dye-sensitized solar cell of claim 6, wherein a sealing member is disposed around a perimeter of the effective area and is configured to seal the electrolyte between the first substrate and the second substrate.

8. The dye-sensitized solar cell of claim 1, wherein the current collector comprises a material with less resistance than the plurality of electrodes.

9. The dye-sensitized solar cell of claim 8, wherein the current collector electrode is formed of silver (Ag), aluminum (Al) or copper (Cu).

10. The dye-sensitized solar cell of claim 1, wherein the width of the current collector is more than about 2 times greater than the width of each of the plurality of electrodes.

11. The dye-sensitized solar cell of claim 10, wherein a ratio of the current collector electrode width to a width of each of the plurality of electrode is between about 2 and about 4.

12. A building integrated photovoltaic (BIPV) device, comprising the dye-sensitized solar cell of claim 1.

13. The BIPV of claim 12, wherein at least part of the effective area is positioned in a window, and wherein at least part of the current collector electrode is positioned in a window frame.

14. A dye-sensitized solar cell, comprising:
a first substrate having a first side and a second side opposite the first side;
a second substrate positioned on the second side of the first substrate;
a first electrode unit positioned between the first substrate and the second substrate and disposed on the first substrate; and
a second electrode unit positioned between the first electrode unit and the second substrate and disposed on the second substrate,
wherein at least one of the first electrode unit and the second electrode unit comprises a current collector electrode and a plurality of electrodes electrically connected to the current collector electrode,
wherein the plurality of electrodes are positioned within an effective area,
wherein the current collector electrode is positioned outside the effective area, and
wherein a current collector electrode width is greater than a width of each of the plurality of electrodes.

15. The dye-sensitized solar cell of claim 14, wherein a ratio of the current collector electrode width to a width of each of the plurality of electrode is between about 2 and about 4

16. The dye-sensitized solar cell of claim 14, wherein the effective area comprises an electrolyte disposed between the first substrate and the second substrate, and wherein a sealing member is disposed around a perimeter of the effective area and is configured to seal the electrolyte between the first substrate and the second substrate.

17. The dye-sensitized solar cell of claim 14, wherein a current collector electrode cross-section area is greater than a cross-section area of each of the plurality of electrodes.

18. The dye-sensitized solar cell of claim 14, wherein the width of the current collector is more than about 2 times greater than the width of each of the plurality of electrodes.

19. The dye-sensitized solar cell of claim 14, wherein the current collector electrode comprises a first current collector electrode and a second current collector electrode, wherein the first current collector electrode comprises a first grid electrode and a semiconductor electrode, and wherein the second current collector electrode comprises a second grid electrode and a counter electrode.

20. The dye-sensitized solar cell of claim 14, wherein the current collector comprises a material with less resistance than the plurality of electrodes.
